(19) United States
(12) Patent Application Publication
(10) Pub. No.: US 2025/0316238 A1
(43) Pub. Date: Oct. 9, 2025

(54) DRIVER AND DISPLAY DEVICE

(71) Applicant: Samsung Display Co., LTD., Yongin-si (KR)

(72) Inventor: CHAEHAN HYUN, Yongin-si (KR)

(73) Assignee: Samsung Display Co., LTD., Yongin-si (KR)

(21) Appl. No.: 18/978,186

(22) Filed: Dec. 12, 2024

(30) Foreign Application Priority Data
Apr. 3, 2024 (KR) 10-2024-0045155

(51) Int. Cl. G09G 3/3266; G09G 3/32; G09G 3/3233

(52) U.S. Cl. CPC G09G 3/3266; G09G 3/32; G09G 3/3233; G09G 2300/0852; G09G 2300/0861; G09G 2310/0286; G09G 2310/08; G09G 2330/021

(57) ABSTRACT

Provided is a driver including multiple stages. At least one stage includes an input circuit that transfers an input signal to a first Q node in response to a first clock signal, a node separating circuit electrically connected between the first Q node and a second Q node, a node controlling circuit that controls a voltage of a QB node based on a voltage of the first Q node, high and low gate voltages and the first and second clock signals, an output circuit that generates an output signal based on the voltages of the QB node and the second Q node and the high and low gate voltages, and a boosting circuit that boosts the voltage of the second Q node to a boosted low level in case that the voltage of the second Q node becomes a low level.

### CROSS-REFERENCE TO RELATED APPLICATION(S)

This application claims priority to and benefits of Korean Patent Application No. 10-2024-0045155 under 35 USC § 119, filed on Apr. 3, 2024, in the Korean Intellectual Property Office, the entire content of which are incorporated herein by reference.

### BACKGROUND

### 1. Technical Field

The disclosure generally relates to a display device, and more particularly to a driver including a plurality of stages, and a display device including the driver.

### 2. Description of the Related Art

A driver (e.g., a gate driver and/or an emission driver) of a display device may sequentially provide signals (e.g., gate signals and/or emission signals) to pixels of a display panel on a row-by-row basis. The driver can be built as a shift register with multiple stages in order to sequentially send the signals on a row-by-row basis.

In a traditional display device, each stage of a driver's output signal may respond to a first clock signal by decreasing from a high gate voltage to an intermediate level voltage, and in response to a second clock signal, it may further reduce from the intermediate level voltage to a low gate voltage.

### SUMMARY

Some embodiments provide a driver in which an output signal of each stage is decreased from a high gate voltage to a low gate voltage at once.

Some embodiments provide a display device including the driver.

According to embodiments, there is provided a driver including a plurality of stages. At least one stage of the plurality of stages includes an input circuit that transfers an input signal to a first Q node in response to a first clock signal, a node separating circuit electrically connected between the first Q node and a second Q node, a node controlling circuit that controls a voltage of a QB node based on a voltage of the first Q node, a high gate voltage, a low gate voltage, the first clock signal and a second clock signal, an output circuit that generates an output signal based on the voltage of the QB node, a voltage of the second Q node, the high gate voltage and the low gate voltage, and a boosting circuit that receives the voltage of the QB node, the high gate voltage and the low gate voltage, and to boost the voltage of the second Q node to a boosted low level in case that the voltage of the second Q node becomes a low level.

In embodiments, the boosting circuit may include a first transistor that applies the high gate voltage to an internal node in response to the voltage of the QB node, a second transistor that applies the low gate voltage to the internal node in response to the voltage of the second Q node, and a first capacitor electrically connected between the second Q node and the internal node.

In embodiments, in case that the voltage of the second Q node becomes the low level, the first transistor may be turned off in response to the voltage of the QB node such that the internal node is electrically separated from a line which transfers the high gate voltage, the second transistor may be turned on in response to the voltage of the second Q node such that a voltage of the internal node is changed from the high gate voltage to the low gate voltage, and the first capacitor may boost the voltage of the second Q node from the low level to the boosted low level based on the voltage of the internal node changed from the high gate voltage to the low gate voltage.

In embodiments, the first transistor may include a gate electrically connected to the QB node, a first terminal which receives the high gate voltage, and a second terminal electrically connected to the internal node, the second transistor may include a gate electrically connected to the second Q node, a first terminal electrically connected to the internal node, and a second terminal which receives the low gate voltage, and the first capacitor may include a first electrode electrically connected to the internal node, and a second electrode electrically connected to the second Q node.

In embodiments, the input circuit may include a third transistor that transfers the input signal to the first Q node in response to the first clock signal.

In embodiments, the third transistor may include a gate which receives the first clock signal, a first terminal which receives the input signal, and a second terminal electrically connected to the first Q node.

In embodiments, the node separating circuit may include a fourth transistor that is turned on in response to the low gate voltage.

In embodiments, the fourth transistor may include a gate which receives the low gate voltage, a first terminal electrically connected to the first Q node, and a second terminal electrically connected to the second Q node.

In embodiments, the node controlling circuit may include a fifth transistor that transfers the first clock signal to a first control node in response to the voltage of the first Q node, a sixth transistor that transfers the low gate voltage to the first control node in response to the first clock signal, a seventh transistor electrically connected between the first control node and a second control node, an eighth transistor that transfers the second clock signal to a third control node in response to a voltage of the second control node, a second capacitor electrically connected between the second control node and the third control node, a ninth transistor that electrically connects the third control node to the QB node in response to the second clock signal, a third capacitor electrically connected between a line which transfers the high gate voltage and the QB node, and a tenth transistor that transfers the high gate voltage to the QB node in response to the voltage of the first Q node.

In embodiments, the fifth transistor may include a gate electrically connected to the first Q node, a first terminal electrically connected to the first control node, and a second terminal which receives the first clock signal, the sixth transistor may include a gate which receives the first clock signal, a first terminal electrically connected to the first control node, and a second terminal which receives the low gate voltage, the seventh transistor may include a gate which receives the low gate voltage, a first terminal electrically connected to the first control node, and a second terminal electrically connected to the second control node, the eighth transistor may include a gate electrically connected to the second control node, a first terminal electrically connected to the third control node, and a second terminal which receives the second clock signal, the second capacitor may include a first electrode electrically connected to the second control node, and a second electrode electrically connected to the third control node, the ninth transistor may include a gate which receives the second clock signal, a first terminal electrically connected to the QB node, and a second terminal which receives the third control node, the third capacitor may include a first electrode electrically connected to the line which transfers the high gate voltage, and a second electrode electrically connected to the QB node, and the tenth transistor may include a gate electrically connected to the first Q node, a first terminal which receives the high gate voltage, and a second terminal electrically connected to the QB node.

In embodiments, the fifth transistor may include a plurality of sub-transistors electrically connected in series between the first control node and a line which transfers the first clock signal.

In embodiments, the output circuit may include an eleventh transistor that outputs the high gate voltage as the output signal in response to the voltage of the QB node, and a twelfth transistor that outputs the low gate voltage as the output signal in response to the voltage of the second Q node.

In embodiments, the eleventh transistor may include a gate electrically connected to the QB node, a first terminal which receives the high gate voltage, and a second terminal electrically connected to an output node at which the output signal is output, and the twelfth transistor may include a gate electrically connected to the second Q node, a first terminal electrically connected to the output node, and a second terminal which receives the low gate voltage.

In embodiments, transistors included in the at least one stage may be P-type metal-oxide-semiconductor (PMOS) transistors.

According to embodiments, there is provided a driver including a plurality of stages. At least one stage of the plurality of stages includes an input circuit that transfers an input signal to a first Q node in response to a first clock signal, a node separating circuit electrically connected between the first Q node and a second Q node, a node controlling circuit that controls a voltage of a QB node based on a voltage of the first Q node, a high gate voltage, a low gate voltage, the first clock signal and a second clock signal, an output circuit that generates an output signal based on the voltage of the QB node, a voltage of the second Q node, the high gate voltage and the low gate voltage, a first transistor including a gate electrically connected to the QB node, a first terminal which receives the high gate voltage, and a second terminal electrically connected to an internal node, a second transistor including a gate electrically connected to the second Q node, a first terminal electrically connected to the internal node, and a second terminal which receives the low gate voltage, and a first capacitor including a first electrode electrically connected to the internal node, and a second electrode electrically connected to the second Q node.

In embodiments, the input circuit may include a third transistor including a gate which receives the first clock signal, a first terminal which receives the input signal, and a second terminal electrically connected to the first Q node. The node separating circuit may include a fourth transistor including a gate which receives the low gate voltage, a first terminal electrically connected to the first Q node, and a second terminal electrically connected to the second Q node. The node controlling circuit may include a fifth transistor including a gate electrically connected to the first Q node, a first terminal electrically connected to a first control node, and a second terminal which receives the first clock signal, a sixth transistor including a gate which receives the first clock signal, a first terminal electrically connected to the first control node, and a second terminal which receives the low gate voltage, a seventh transistor including a gate which receives the low gate voltage, a first terminal electrically connected to the first control node, and a second terminal electrically connected to a second control node, an eighth transistor including a gate electrically connected to the second control node, a first terminal electrically connected to a third control node, and a second terminal which receives the second clock signal, a second capacitor including a first electrode electrically connected to the second control node, and a second electrode electrically connected to the third control node, a ninth transistor including a gate which receives the second clock signal, a first terminal electrically connected to the QB node, and a second terminal which receives the third control node, a third capacitor including a first electrode electrically connected to a line which transfers the high gate voltage, and a second electrode electrically connected to the QB node, and a tenth transistor including a gate electrically connected to the first Q node, a first terminal which receives the high gate voltage, and a second terminal electrically connected to the QB node. The output circuit may include an eleventh transistor including a gate electrically connected to the QB node, a first terminal which receives the high gate voltage, and a second terminal electrically connected to an output node at which the output signal is output, and a twelfth transistor including a gate electrically connected to the second Q node, a first terminal electrically connected to the output node, and a second terminal which receives the low gate voltage.

According to embodiments, there is provided a display device including a display panel including a plurality of pixels, a data driver that provides data signals to the plurality of pixels, a gate driver that provides gate signals to the plurality of pixels, an emission driver that provides emission signals to the plurality of pixels, and a controller that controls the data driver, the gate driver and the emission driver at least by providing inputs to each of the data driver, the gate driver, and the emission driver. At least one of the gate driver and the emission driver includes a plurality of stages. At least one stage of the plurality of stages includes an input circuit that transfers an input signal to a first Q node in response to a first clock signal, a node separating circuit electrically connected between the first Q node and a second Q node, a node controlling circuit that controls a voltage of a QB node based on a voltage of the first Q node, a high gate voltage, a low gate voltage, the first clock signal and a second clock signal, an output circuit that generates an output signal based on the voltage of the QB node, a voltage of the second Q node, the high gate voltage and the low gate voltage, and a boosting circuit that receives the voltage of the QB node, the high gate voltage and the low gate voltage, and to boost the voltage of the second Q node to a boosted low level in case that the voltage of the second Q node becomes a low level.

In embodiments, the boosting circuit may include a first transistor that applies the high gate voltage to an internal node in response to the voltage of the QB node, a second transistor that applies the low gate voltage to the internal node in response to the voltage of the second Q node, and a first capacitor electrically connected between the second Q node and the internal node.

In embodiments, in case that the voltage of the second Q node becomes the low level, the first transistor may be turned off in response to the voltage of the QB node such that the internal node is electrically separated from a line which transfers the high gate voltage, the second transistor may be turned on in response to the voltage of the second Q node such that a voltage of the internal node is changed from the high gate voltage to the low gate voltage, and the first capacitor may boost the voltage of the second Q node from the low level to the boosted low level based on the voltage of the internal node changed from the high gate voltage to the low gate voltage.

In embodiments, the first transistor may include a gate electrically connected to the QB node, a first terminal which receives the high gate voltage, and a second terminal electrically connected to the internal node, the second transistor may include a gate electrically connected to the second Q node, a first terminal electrically connected to the internal node, and a second terminal which receives the low gate voltage, and the first capacitor may include a first electrode electrically connected to the internal node, and a second electrode electrically connected to the second Q node.

As described above, in a driver and a display device according to embodiments, each stage of the driver may include a boosting circuit that boosts a voltage of a second Q node to a boosted low level. Accordingly, an output signal of each stage of the driver may be changed from a high gate voltage to a low gate voltage at once.

### BRIEF DESCRIPTION OF THE DRAWINGS

Illustrative, non-limiting embodiments will be more clearly understood from the following detailed description in conjunction with the accompanying drawings.

FIG. 1 is a schematic block diagram illustrating a driver according to embodiments.

FIG. 2 is a schematic timing diagram for describing an operation of a driver of FIG. 1.

FIG. 3 is a schematic circuit diagram illustrating a stage of a driver according to embodiments.

FIG. 4 is a schematic timing diagram for describing an example of an operation of a stage of FIG. 3.

FIG. 5 is a schematic circuit diagram for describing an example of an operation of a stage of FIG. 3 in a first time period.

FIG. 6 is a schematic circuit diagram for describing an example of an operation of a stage of FIG. 3 in a second time period.

FIG. 7 is a schematic circuit diagram for describing an example of an operation of a stage of FIG. 3 in a third time period.

FIG. 8 is a schematic timing diagram illustrating examples of an output signal of a conventional driver and an output signal of a driver according to embodiments.

FIG. 9 is a schematic block diagram illustrating a display device according to embodiments.

FIG. 10 is a schematic circuit diagram illustrating an example of a pixel included in a display device according to embodiments.

FIG. 11 is a schematic block diagram illustrating an electronic device including a display device according to embodiments.

### DETAILED DESCRIPTION OF EMBODIMENTS

The embodiments are described more fully hereinafter with reference to the accompanying drawings. Like or similar reference numerals refer to like or similar elements throughout.

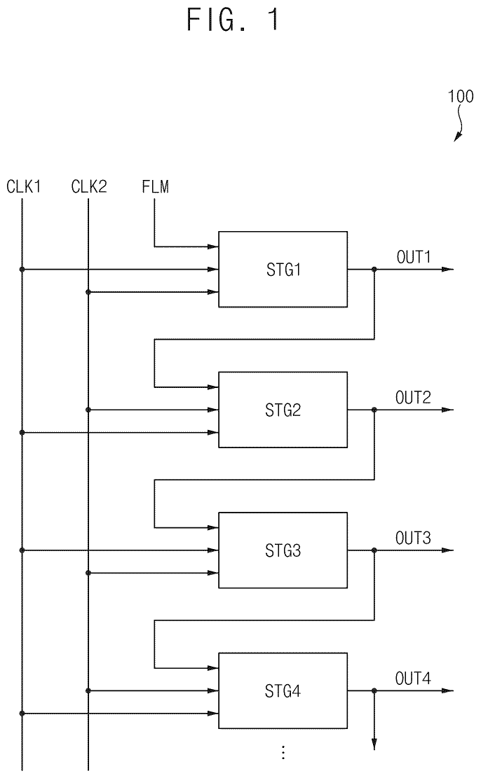

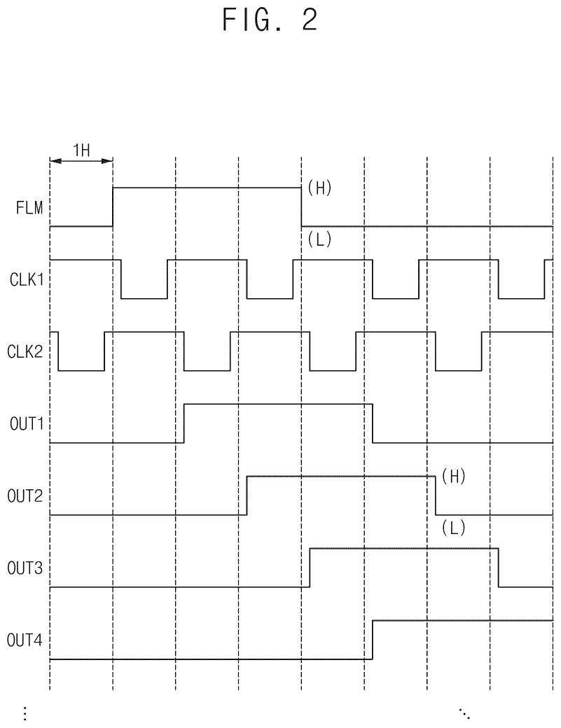

FIG. 1 is a schematic block diagram illustrating a driver according to embodiments, and FIG. 2 is a timing diagram for describing an operation of a driver of FIG. 1.

Referring to FIG. 1, a driver 100 according to embodiments may include multiple stages STG1, STG2, STG3, STG4, etc. The driver 100 may be implemented in the form of a shift register in which the stages STG1, STG2, STG3, STG4, etc. sequentially produce output signals OUT1, OUT2, OUT3, OUT4, etc.

The stages STG1, STG2, STG3, STG4, etc. may sequentially produce the output signals OUT1, OUT2, OUT3, OUT4, etc. based on a start signal FLM, a first clock signal CLK1 and a second clock signal CLK2. Further, a first stage STG1 may receive a start signal FLM as an input signal, and each of subsequent stages STG2, STG3, STG4, etc. may receive an output signal of a previous stage as an input signal. For example, a second stage STG2 may receive a first output signal OUT1 of the first stage STG1 as an input signal, a third stage STG3 may receive a second output signal OUT2 of the second stage STG2 as an input signal, and a fourth stage STG4 may receive a third output signal OUT3 of the third stage STG3 as an input signal.

In some embodiments, each of odd-numbered stages STG1, STG3, etc. may receive an input signal in case that the first clock signal CLK1 has a low level, and each of even-numbered stages STG2, STG4, etc. may receive an input signal in case that the second clock signal CLK2 has the low level. Further, each odd-numbered stage STG1, STG3, etc. may start outputting the output signal OUT1, OUT3, etc. having a high level in case that the second clock signal CLK2 has the low level, and each even-numbered stage STG2, STG4, etc. may start outputting the output signal OUT2, OUT4, etc. having the high level in case that the first clock signal CLK1 has the low level.

For example, as illustrated in FIGS. 1 and 2, in case that the start signal FLM has the high level and the first clock signal CLK1 has the low level, the first stage STG1 may receive the start signal FLM having the high level. Further, in case that the start signal FLM has the high level and the second clock signal CLK2 has the low level, the first stage STG1 may output the first output signal OUT1 having the high level. Further, in case that the start signal FLM has the low level and the first clock signal CLK1 has the low level, the first stage STG1 may receive the start signal FLM having the low level, and may output the first output signal OUT1 having the low level.

In case that the first output signal OUT1 has the high level, and the second clock signal CLK2 has the low level, the second stage STG2 may receive the first output signal OUT1 having the high level. Further, in case that the first output signal OUT1 has the high level, and the first clock signal CLK1 has the low level, the second stage STG2 may produce the second output signal OUT2 having the high level. Further, in case that the first output signal OUT1 has the low level, and the second clock signal CLK2 has the low level, the second stage STG2 may receive the first output signal OUT1 having the low level, and may produce the second output signal OUT2 having the low level.

In case that the second output signal OUT2 has the high level, and the first clock signal CLK1 has the low level, the third stage STG3 may receive the second output signal OUT2 having the high level. Further, in case that the second output signal OUT2 has the high level, and the second clock signal CLK2 has the low level, the third stage STG3 may produce the third output signal OUT3 having the high level. Further, in case that the second output signal OUT2 has the low level, and the first clock signal CLK1 has the low level, the third stage STG3 may receive the second output signal OUT2 having the low level, and may produce a third output signal OUT3 having the low level.

In case that the third output signal OUT3 has the high level, and the second clock signal CLK2 has the low level, the fourth stage STG4 may receive the third output signal OUT3 having the high level. Further, in case that the third output signal OUT3 has the high level, and the first clock signal CLK1 has the low level, the fourth stage STG4 may produce a fourth output signal OUT4 having the high level. Further, in case that the third output signal OUT3 has the low level, and the second clock signal CLK2 has the low level, the fourth stage STG4 may receive the third output signal OUT3 having the low level, and may produce the fourth output signal OUT4 having the low level.

The stages STG1, STG2, STG3, STG4, etc. may sequentially produce the output signals OUT1, OUT2, OUT3, OUT4, etc. by delaying or shifting the output signals OUT1, OUT2, OUT3, OUT4, etc. by one horizontal time 1 H. For example, one horizontal time 1 H may be a time allocated to each pixel row of a display panel, and may be determined by dividing one frame period by the number of pixel rows of the display panel, but is not limited thereto. Thus, one horizontal time 1 H may correspond to one half of a period (or a cycle) of the first clock signal CLK1 or the second clock signal CLK2. For example, the period of each of the first and second clock signals CLK1 and CLK2 may correspond to two horizontal times, but is not limited thereto. As illustrated in FIG. 2, an on-period (e.g., a low-level period) of each of the first and second clock signals CLK1 and CLK2 may be shorter than an off-period (e.g., a high-level period) of each of the first and second clock signals CLK1 and CLK2, but is not limited thereto. In other embodiments, the on-period of each of the first and second clock signals CLK1 and CLK2 may have substantially the same time length as the off-period of each of the first and second clock signals CLK1 and CLK2.

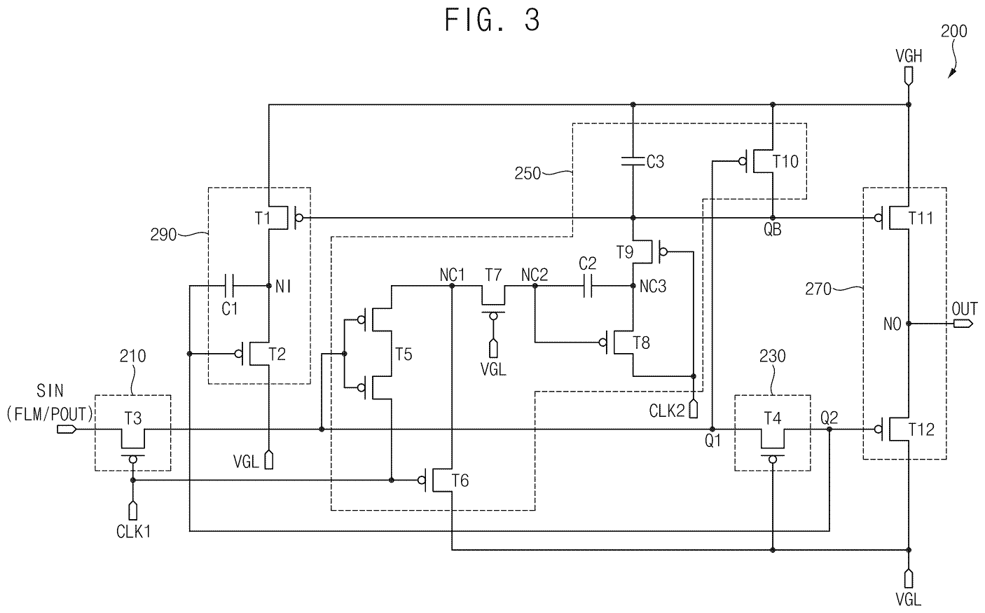

FIG. 3 is a schematic circuit diagram illustrating a stage of a driver according to embodiments.

Referring to FIG. 3, each stage 200 of a driver according to embodiments may include an input circuit 210, a node separating circuit 230, a node controlling circuit 250, an output circuit 270, and a boosting circuit 290.

The input circuit 210 may receive an input signal SIN from an external source and transfer the input signal SIN to a first Q node Q1 in response to a first clock signal CLK1. In case that the stage 200 is an even-numbered stage such as STG2 or STG4 as shown in FIG. 1, the input circuit 210 may receive a second clock signal CLK2 instead of the first clock signal CLK1. Further, the input signal SIN may be a start signal FLM in case that the stage 200 is a first stage, and may be an output signal OUT of a previous stage in case that the stage 200 is a subsequent stage.

The input circuit 210 may include a third transistor T3. The third transistor T3 may transfer the input signal SIN to the first Q node Q1 in response to the first clock signal CLK1. Further, the third transistor T3 may include a gate which receives the first clock signal CLK1, a first terminal which receives the input signal SIN, and a second terminal electrically connected to the first Q node Q1.

The node separating circuit 230 may be electrically connected between the first Q node Q1 and a second Q node Q2. The node separating circuit 230 may electrically connect the first Q node Q1 and the second Q node Q2 to each other in most periods, but may electrically separate the first Q node Q1 and the second Q node Q2 from each other in case that a voltage of the first Q node Q1 is boosted.

The node separating circuit 230 may include a fourth transistor T4 that is turned on in response to a low gate voltage VGL. The fourth transistor T4 may be turned on in most periods except for a period in which the voltage of the first Q node Q1 is boosted, and thus may be referred to as an always-on transistor (“AOT”). Further, the fourth transistor T4 may include a gate which receives the low gate voltage VGL, a first terminal electrically connected to the first Q node Q1, and a second terminal electrically connected to the second Q node Q2.

The node controlling circuit 250 may control a voltage of a QB node QB based on the voltage of the first Q node Q1, a high gate voltage VGH, the low gate voltage VGL, the first clock signal CLK1, and the second clock signal CLK2. For example, the node controlling circuit 250 may change the voltage of the QB node QB from a high level to a low level in case that the voltage of the first Q node Q1 has the high level, and the second clock signal CLK2 has the low level, and may control the voltage of the QB node QB to the high level in case that the voltage of the first Q node Q1 has the low level.

The node controlling circuit 250 may include a fifth transistor T5 that transfers the first clock signal CLK1 to a first control node NC1 in response to the voltage of the first Q node Q1, a sixth transistor T6 that transfers the low gate voltage VGL to the first control node NC1 in response to the first clock signal CLK1, a seventh transistor T7 electrically connected between the first control node NC1 and a second control node NC2, an eighth transistor T8 that transfers the second clock signal CLK2 to a third control node NC3 in response to a voltage of the second control node NC2, a second capacitor C2 electrically connected between the second control node NC2 and the third control node NC3, a ninth transistor T9 that electrically connects the third control node NC3 to the QB node QB in response to the second clock signal CLK2, a third capacitor C3 electrically connected between a line which transfers the high gate voltage VGH and the QB node QB, and a tenth transistor T10 that transfers the high gate voltage VGH to the QB node QB in response to the voltage of the first Q node Q1. Further, the fifth transistor T5 may include a gate electrically connected to the first Q node Q1, a first terminal electrically connected to the first control node NC1, and a second terminal which receives the first clock signal CLK1, the sixth transistor T6 may include a gate which receives the first clock signal CLK1, a first terminal electrically connected to the first control node NC1, and a second terminal which receives the low gate voltage VGL, the seventh transistor T7 may include a gate which receives the low gate voltage VGL, a first terminal electrically connected to the first control node NC1, and a second terminal electrically connected to the second control node NC2, the eighth transistor T8 may include a gate electrically connected to the second control node NC2, a first terminal electrically connected to the third control node NC3, and a second terminal which receives the second clock signal CLK2, the second capacitor C2 may include a first electrode electrically connected to the second control node NC2, and a second electrode electrically connected to the third control node NC3, the ninth transistor T9 may include a gate which receives the second clock signal CLK2, a first terminal electrically connected to the QB node QB, and a second terminal electrically connected to the third control node NC3, the third capacitor C3 may include a first electrode electrically connected to the line which transfers the high gate voltage VGH, and a second electrode electrically connected to the QB node QB, and the tenth transistor T10 may include a gate electrically connected to the first Q node Q1, a first terminal which receives the high gate voltage VGH, and a second terminal electrically connected to the QB node QB. The seventh transistor T7 may have the gate which receives the low gate voltage VGL, and thus may be referred to as an always-on transistor (“AOT”). Further, as illustrated in FIG. 3, the fifth transistor T5 may include multiple sub-transistors which are electrically connected in series between the first control node NC1 and a line which transfers the first clock signal CLK1, but is not limited thereto.

The output circuit 270 may generate an output signal OUT based on the voltage of the QB node QB, the voltage of the second Q node Q2, the high gate voltage VGH, and the low gate voltage VGL. For example, the output circuit 270 may generate the high gate voltage VGH as the output signal OUT in case that the voltage of the QB node QB has the low level, and may generate the low gate voltage VGL as the output signal OUT in case that the voltage of the second Q node Q2 has the low level (or a boosted low level).

The output circuit 270 may include an eleventh transistor T11 that generates the high gate voltage VGH as the output signal OUT in response to the voltage of the QB node QB, and a twelfth transistor T12 that generates the low gate voltage VGL as the output signal OUT in response to the voltage of the second Q node Q2. Further, the eleventh transistor T11 may include a gate electrically connected to the QB node QB, a first terminal which receives the high gate voltage VGH, and a second terminal electrically connected to an output node NO from which the output signal OUT is generated, and the twelfth transistor T12 may include a gate electrically connected to the second Q node Q2, a first terminal electrically connected to the output node NO, and a second terminal which receives the low gate voltage VGL.

The boosting circuit 290 may receive the voltage of the QB node QB, the high gate voltage VGH and the low gate voltage VGL. In case that the voltage of the second Q node Q2 becomes the low level, the boosting circuit 290 may boost the voltage of the second Q node Q2 such that the voltage of the second Q node Q2 has the boosted low level. For example, at a time point in case that the input signal SIN having the low level is applied to the second Q node Q2 through the third and fourth transistors T3 and T4, or at a time point in case that the voltage of the second Q node Q2 changes from the high level to the low level of the input signal SIN, the voltage of the second Q node Q2 may be boosted to a level lower than the low level of the input signal SIN.

The boosting circuit 290 may include a first transistor T1 that applies the high gate voltage VGH to an internal node NI in response to the voltage of the QB node QB, a second transistor T2 that applies the low gate voltage VGL to the internal node NI in response to the voltage of the second Q node Q2, and a first capacitor C1 electrically connected between the second Q node Q2 and the internal node NI. In case that the voltage of the second Q node Q2 becomes the low level, the first transistor T1 may be turned off in response to the voltage of the QB node QB such that the internal node NI may be electrically separated from the line which transfers the high gate voltage VGH, the second transistor T2 may be turned on in response to the voltage of the second Q node Q2 such that a voltage of the internal node NI may change from the high level to the low level, or from the high gate voltage VGH to the low gate voltage VGL, and the first capacitor C1 may boost the voltage of the second Q node Q2 from the low level to the boosted low level based on the voltage of the internal node NI changed from the high gate voltage VGH to the low gate voltage VGL. The first transistor T1 may include a gate electrically connected to the QB node QB, a first terminal which receives the high gate voltage VGH, and a second terminal connected to the internal node NI, the second transistor T2 may include a gate electrically connected to the second Q node Q2, a first terminal electrically connected to the internal node NI, and a second terminal which receives the low gate voltage VGL, and the first capacitor C1 may include a first electrode electrically connected to the internal node NI, and a second electrode electrically connected to the second Q node Q2.

As illustrated in FIG. 3, the first through twelfth transistors T1 through T12 included in the stage 200 may be P-type metal-oxide-semiconductor (“PMOS”) transistors. However, in other embodiments, at least one of the first through twelfth transistors T1 through T12 included in the stage 200 may be an N-type metal-oxide-semiconductor (“NMOS”) transistor.

Hereinafter, an example of an operation of the stage 200 will be described below with reference to FIGS. 3 to 8.

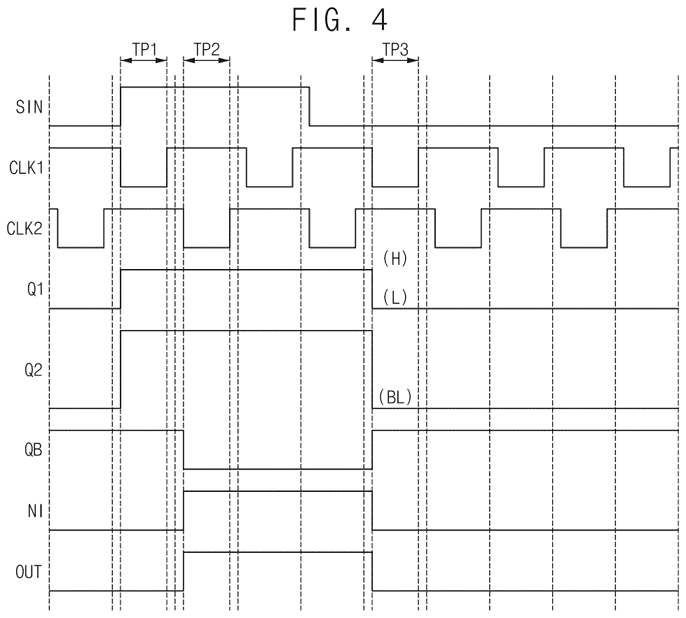

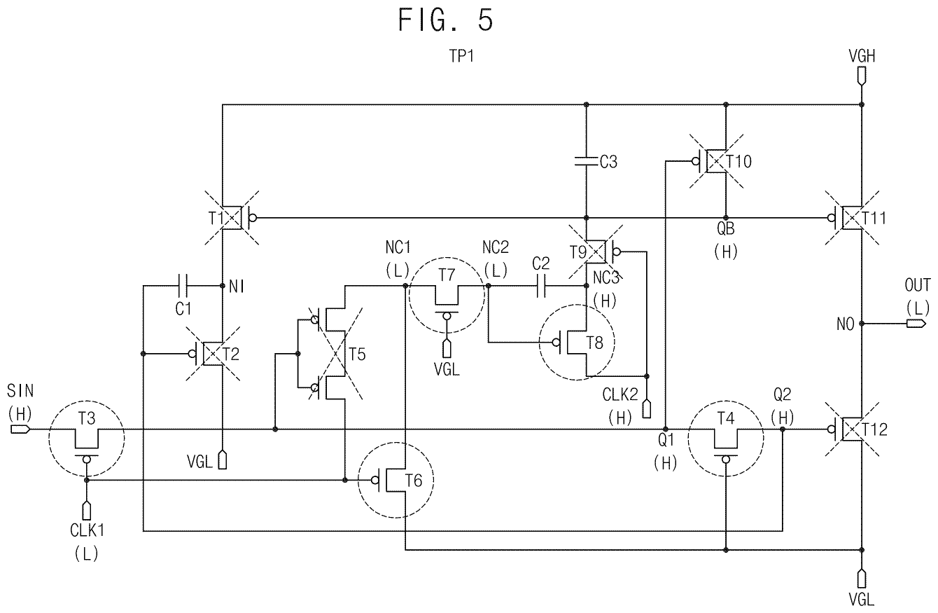

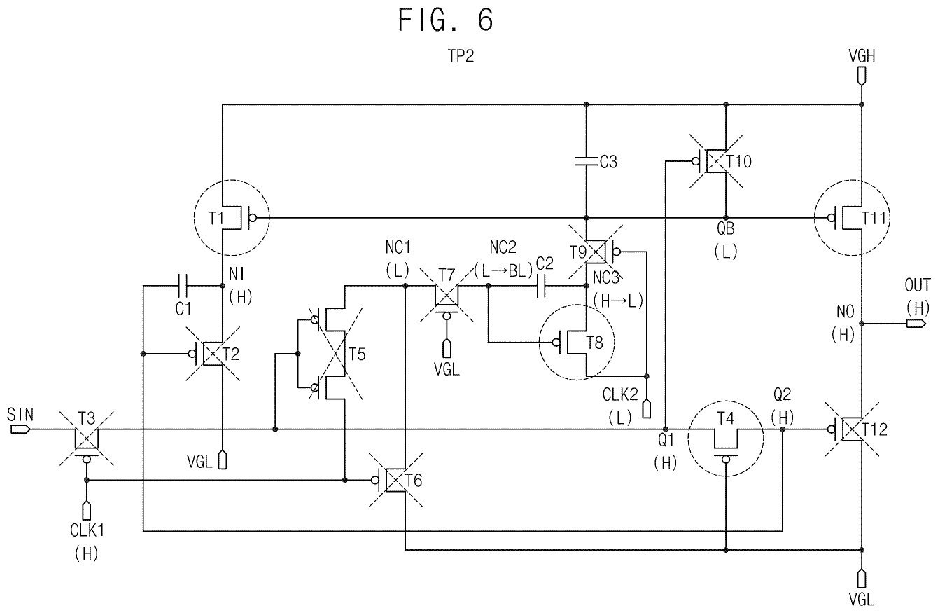

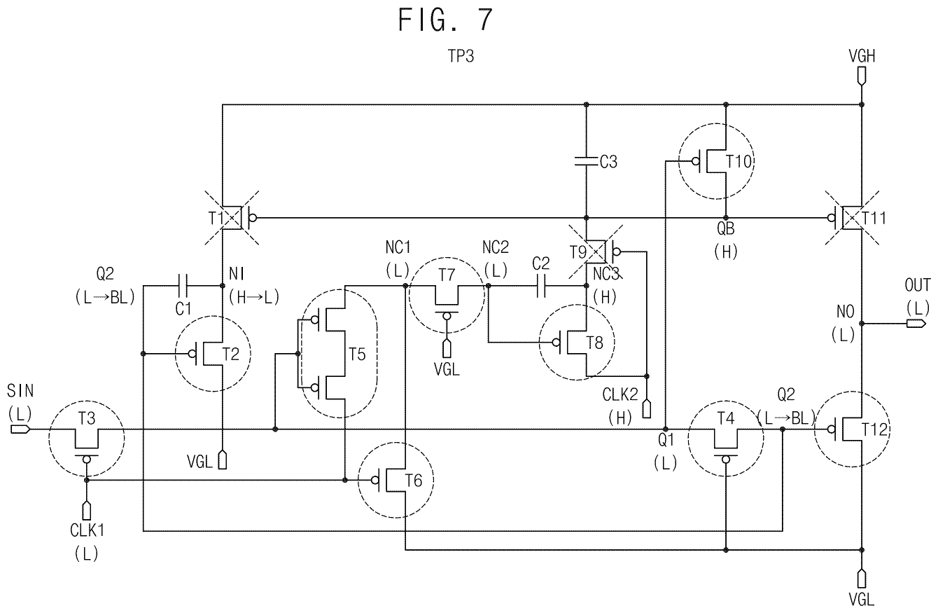

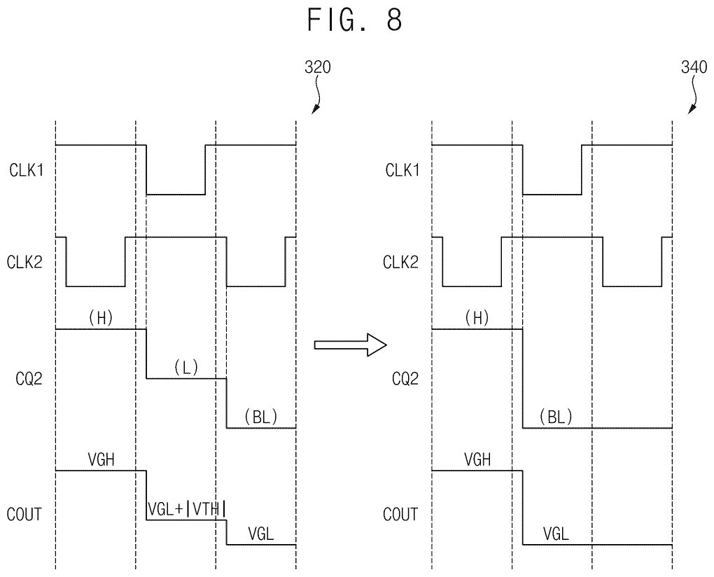

FIG. 4 is a schematic timing diagram for describing an example of an operation of a stage of FIG. 3, FIG. 5 is a schematic circuit diagram for describing an example of an operation of a stage of FIG. 3 in a first time period, FIG. 6 is a circuit diagram for describing an example of an operation of a stage of FIG. 3 in a second time period, FIG. 7 is a schematic circuit diagram for describing an example of an operation of a stage of FIG. 3 in a third time period, and FIG. 8 is a schematic timing diagram illustrating examples of an output signal of a conventional driver and an output signal of a driver according to embodiments.

Referring to FIGS. 3 and 4, in a first time period TP1 in which the input signal SIN has the high level and the first clock signal CLK1 has the low level, the stage 200 may receive the input signal SIN having the high level, and may change the voltage of the first Q node Q1 and the voltage of the second Q node Q2 to the high level based on the input signal SIN having the high level.

For example, as illustrated in FIG. 5, in the first time period TP1, the third transistor T3 may be turned on in response to the first clock signal CLK1 having the low level L, and may transfer the input signal SIN having the high level H to the first Q node Q1. Thus, the voltage of the first Q node Q1 may have the high level H. Further, the fourth transistor T4 may be turned on in response to the low gate voltage VGL, and may transfer the voltage of the first Q node Q1 having the high level H to the second Q node Q2. Thus, the voltage of the second Q node Q2 also may have the high level H. Further, the sixth transistor T6 may transfer the low gate voltage VGL to the first control node NC1 in response to the first clock signal CLK1, the seventh transistor T7 may transfer the voltage of the first control node NC1 to the second control node NC2 in response to the low gate voltage VGL, and the eighth transistor T8 may transfer the second clock signal CLK2 having the high level H to the third control node NC3 in response to the voltage of the second control node NC2. The first, second, fifth, ninth, tenth, eleventh, and twelfth transistors T1, T2, T5, T9, T10, T11, and T12 may be turned off. Since the eleventh and twelfth transistors T11 and T12 are turned off, the output node NO may be floated, and the output signal OUT may be maintained at a previous level, or the low level L.

Thereafter, in a second time period TP2 in which the input signal SIN has the high level H and the second clock signal CLK2 has the low level L, the stage 200 may change the voltage of the QB node QB to the low level L, may change the voltage of the internal node NI to the high level H, and may start outputting the output signal OUT having the high level H, or the high gate voltage VGH.

For example, as illustrated in FIG. 6, in the second time period TP2, the eighth transistor T8 may be turned on in response to the voltage of the second control node NC2 having the low level L and may transfer the second clock signal CLK2 having the low level L to the third control node NC3. Thus, the voltage of the third control node NC3 may change from the high level H to the low level L. Further, in case that the voltage of the third control node NC3 electrically connected to the second electrode of the second capacitor C2 decreases from the high level H to the low level L, the voltage of the second control node NC2 electrically connected to the first electrode of the second capacitor C2 also may decrease from the low level L to the boosted low level BL. Accordingly, the eighth transistor T8 may be fully or completely turned on. In case that the voltage of the second control node NC2 has the boosted low level BL lower than a voltage level of the low gate voltage VGL, the seventh transistor T7 may be turned off, and the voltage of the second control node NC2 may not be transferred to the first control node NC1. Further, the ninth transistor T9 may be turned on in response to the second clock signal CLK2 having the low level L, and may transfer the voltage of the third control node NC3 having the low level L to the QB node QB. Thus, the voltage of the QB node QB may have the low level L. Further, the first transistor Tl may be turned on in response to the voltage of the QB node QB having the low level L, and may transfer the high gate voltage VGH to the internal node NI. Thus, the voltage of the internal node NI may have the high level H. Further, the eleventh transistor T11 may be turned on in response to the voltage of the QB node QB having the low level L, and may transfer the high gate voltage VGH to the output node NO. Accordingly, the stage 200 may output the high gate voltage VGH as the output signal OUT having the high level H at the output node NO. The seventh transistor T7 may be turned on, and the second, third, fifth, sixth, tenth, and twelfth transistors T2, T3, T5, T6, T10, and T12 may be turned off.

Thereafter, in a third time period TP3 in which the input signal SIN has the low level L and the first clock signal CLK1 has the low level L, the stage 200 may change the voltage of the first Q node Q1 and the voltage of the internal node NI to the low level L, may change the voltage of the QB node QB to the high level H, may change the voltage of the second Q node Q2 to the boosted low level BL, and may start generating the output signal OUT having the low level L, or the low gate voltage VGL.

For example, as illustrated in FIG. 7, in the third time period TP3, the third transistor T3 may be turned on in response to the first clock signal CLK1 having the low level L, and may transfer the input signal SIN having the low level L to the first Q node Q1. Thus, the voltage of the first Q node Q1 may have the low level L. Further, the fourth transistor T4 may be turned on in response to the low gate voltage VGL, and may transfer the voltage of the first Q node Q1 having the low level L to the second Q node Q2. Thus, the voltage of the second Q node Q2 may change from the high level H to the low level L. Further, the tenth transistor T10 may be turned on in response to the voltage of the first Q node Q1 having the low level L, and may transfer the high gate voltage VGH to the QB node QB. Thus, the voltage of the QB node QB may have the high level H. The first transistor T1 may be turned off in response to the voltage of the QB node QB having the high level H, and may electrically separate the internal node NI from the line which transfers the high gate voltage VGH. Further, the second transistor T2 may be turned on in response to the voltage of the second Q node Q2 having the low level L, and may transfer the low gate voltage VGL to the internal node NI. Thus, the voltage of the internal node NI may change from the high level H to the low level L. Further, in case that the voltage of the internal node NI electrically connected to the first electrode of the first capacitor C1 decreases from the high level H to the low level L, the voltage of the second Q node Q2 electrically connected to the second electrode of the first capacitor Cl also may decrease from the low level L to the boosted low level BL. For example, by the first capacitor C1, the voltage of the second Q node Q2 may be boosted from the low level L to the boosted low level BL. In case that the voltage of the second Q node Q2 has the boosted low level BL lower than the voltage level of the low gate voltage VGL, the fourth transistor T4 may be turned off, and the voltage of the second Q node Q2 may not be transferred to the first Q node Q1. Further, in case that the voltage of the second Q node Q2 has the boosted low level BL, the twelfth transistor T12 may be fully or completely turned on. Accordingly, the twelfth transistor T12 may transfer the low gate voltage VGL to the output node NO as it is without being affected by a threshold voltage of the twelfth transistor T12. Accordingly, the stage 200 may generate the low gate voltage VGL as the output signal OUT having the low level L at the output node NO.

In a conventional driver (or comparative driver) that does not have the boosting circuit 290 which boosts the voltage of the QB node QB, as illustrated in a first timing diagram 320 of FIG. 8, a voltage of a second Q node CQ2 may be changed to the low level L in response to the first clock signal CLK1, and may be further changed to the boosted low level BL in response to the second clock signal CLK2. For example, a comparative output signal COUT from the first timing diagram 320 may not be changed from the high gate voltage VGH to the low gate voltage VGL at once. For example, the comparative output signal COUT may be changed to a sum of the low gate voltage VGL and an absolute value |VTH| of a threshold voltage (for example, a threshold voltage of the twelfth transistor T12) in response to the first clock signal CLK1, and may be changed to the low gate voltage VGL in response to the second clock signal CLK2.

However, in the stage 200 of the driver according to embodiments, as illustrated in a second timing diagram 340 of FIG. 8, in case that the input signal SIN having the low level L is applied to the second Q node Q2, or in case that the voltage of the second Q node Q2 changes from the high level H to the low level L, the boosting circuit 290 may boost the voltage of the second Q node Q2 such that the voltage of the second Q node Q2 may have the boosted low level BL. For example, the voltage of the second Q node Q2 may be changed from the high level H to the boosted low level BL in response to the first clock signal CLK1. Accordingly, in the stage 200 of the driver according to embodiments, at a time point in case that the first clock signal CLK1 having the low level L is applied, the twelfth transistor T12 may be fully turned on in response to the voltage of the second Q node Q2 having the boosted low level BL. Thus, at the time point in case that the first clock signal CLK1 having the low level L is applied, the stage 200 of the driver according to embodiments may generate the low gate voltage VGL as the output signal OUT having the low level L without the voltage increase by the absolute value |VTH| of the threshold voltage of the twelfth transistor T12. For example, the stage 200 of the driver according to embodiments may change the output signal OUT from the high gate voltage VGH to the low gate voltage VGL at once.

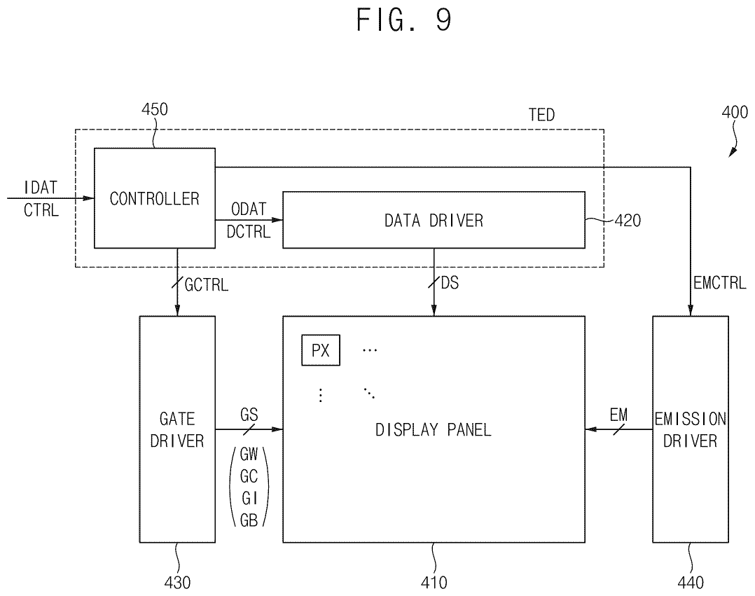

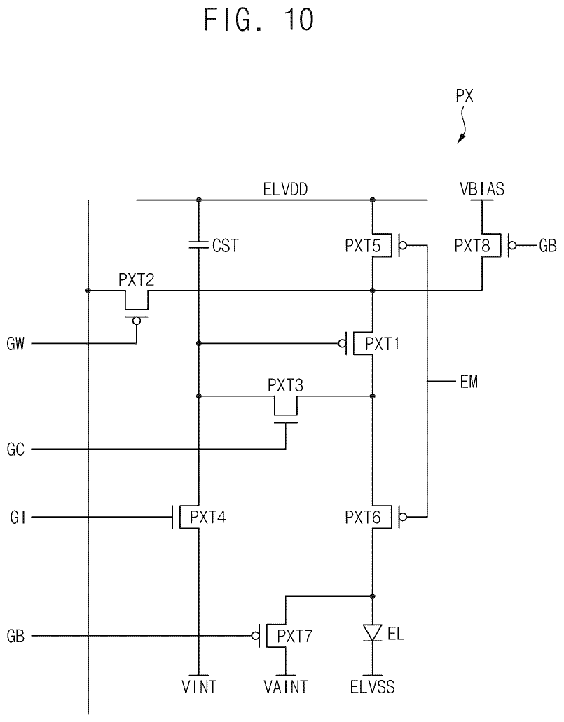

FIG. 9 is a schematic block diagram illustrating a display device according to embodiments, and FIG. 10 is a schematic circuit diagram illustrating an example of a pixel included in a display device according to embodiments.

Referring to FIG. 9, a display device 400 according to embodiments may include a display panel 410 that includes a plurality of pixels PX, a data driver 420 that provides data signals DS to the multiple pixels PX, a gate driver 430 that provides gate signals GS to the multiple pixels PX, an emission driver 440 that provides emission signals EM to the multiple pixels PX, and a controller 450 that controls the data driver 420, the gate driver 430, and the emission driver 440.

The display panel 410 may include data lines, gate lines, emission lines, and multiple pixels PX electrically connected thereto. Each pixel PX may include a light emitting element, and the display panel 410 may be a light emitting display panel. However, the display panel 410 is not limited to the light emitting display panel, and may be any suitable display panel.

For example, as illustrated in FIG. 10, each pixel PX may include a driving transistor PXT1 that generates a driving current, a switching transistor PXT2 that transfers the data signal DS to a source of the driving transistor PXT1 in response to a write signal GW, a compensation transistor PXT3 that diode-connects the driving transistor PXT1 in response to a compensation signal GC, a storage capacitor CST that stores the data signal DS transferred through the switching transistor PXT2 and the diode-connected driving transistor PXT1, a gate initialization transistor PXT4 that provides an initialization voltage VINT to the storage capacitor CST and a gate of the driving transistor PXT1 in response to an initialization signal GI, a first emission transistor PXT5 that electrically connects a line which transfers a first power supply voltage ELVDD to the source of the driving transistor PXT1 in response to the emission signal EM, a second emission transistor PXT6 that electrically connects a drain of the driving transistor PXT1 to a light emitting element EL in response to the emission signal EM, an anode initialization transistor PXT7 that provides an anode initialization voltage VAINT to the light emitting element EL in response to a bypass signal GB, and the light emitting element EL that emits light based on the driving current flowing from the line which transfers the first power supply voltage ELVDD (e.g., a high power supply voltage) to a line which transfers a second power supply voltage ELVSS (e.g., a low power supply voltage). Each pixel PX may further include a bias transistor PXT8 that is electrically connected to the driving transistor PXT1, the switching transistor PXT2, and the first emission transistor PXT5. For example, the bias transistor PXT8 applies a bias voltage VBIAS to the source of the driving transistor PXT1 in response to the bypass signal GB.

At least a portion of transistors PXT1 through PXT8 included in each pixel PX may be implemented as NMOS transistors, and the remaining portion of the transistors PXT1 through PXT8 included in each pixel PX may be implemented as PMOS transistors. For example, as illustrated in FIG. 10, the compensation transistor PXT3 and the gate initialization transistor PXT4 may be implemented as NMOS transistors, and the remaining transistors PXT1, PXT2, and PXT5 through PXT8 may be implemented as PMOS transistors. In other embodiments, all of the transistors PXT1 through PXT8 of each pixel PX may be implemented as PMOS transistors, or may be implemented as the NMOS transistors.

Further, the light emitting element EL may be, but is not limited to, an organic light emitting diode (“OLED”). In other embodiments, the light emitting element EL may be a nano light emitting diode (“NED”), a quantum dot (“QD”) light emitting diode, a micro light emitting diode, an inorganic light emitting diode, or any other suitable light emitting element.

Although FIG. 10 illustrates an example in which each pixel PX has an 8TIC structure including eight transistors PXT1 through PXT8 and one capacitor CST, each pixel PX of the display device 400 according to embodiments is not limited to the 8TIC structure illustrated in FIG. 10, and may have any pixel structure. For example, each pixel PX may include more or less than eight transistors and more or less than one capacitor.

Referring back to FIG. 9, the data driver 420 may generate the data signals DS based on a data control signal DCTRL and output image data ODAT received from the controller 450, and may provide the data signals DS to the pixels PX through the data lines. In this case, the data control signal DCTRL may include, but is not limited to, an output data enable signal, a horizontal start signal, and a load signal. The data driver 420 and the controller 450 may be implemented as a single integrated circuit, and the single integrated circuit may be referred to as a timing controller embedded data driver (“TED”) integrated circuit. In other embodiments, the data driver 420 and the controller 450 may be implemented as separate integrated circuits.

The gate driver 430 may generate the gate signals GS based on a gate control signal GCTRL received from the controller 450, and may sequentially provide the gate signals GS to the pixels PX through the gate lines on a row-by-row basis. In this case, the gate signals GS may include the write signal GW, the compensation signal GC, the initialization signal GI, and/or the bypass signal GB. Further, the gate control signal GCTRL may include, but is not limited to, a gate start signal and a gate clock signal. The gate driver 430 may be a driver 100 of FIG. 1 including a stage 200 of FIG. 3. For example, in the gate driver 430, if each stage that generates the compensation signal GC is implemented as the stage 200 of FIG. 3, the compensation signal GC may be changed from a high gate voltage to a low gate voltage substantially all at once, and a horizontal line defect may not occur in an image displayed on the display panel 410. Further, for example, in the gate driver 430, if each stage that generates the bypass signal GB is implemented as the stage 200 of FIG. 3, the bypass signal GB may be changed from the high gate voltage to the low gate voltage substantially all at once, and a time period during which the bypass signal GB has the low gate voltage to apply the anode initialization voltage VAINT and/or the bias voltage VBIAS may be increased. Further, the gate driver 430 may be integrated or formed in the display panel 410. In other embodiments, the gate driver 430 may be implemented as one or more integrated circuits.

The emission driver 440 may generate the emission signals EM based on an emission control signal EMCTRL received from the controller 450, and may sequentially provide the emission signals EM to the pixels PX through the emission lines on a row-by-row basis. The emission control signal EMCTRL may include, but is not limited to, an emission start signal and an emission clock signal. The emission driver 440 may be the driver 100 of FIG. 1 including the stage 200 of FIG. 3. For example, in the emission driver 440, if each stage that generates the emission signal EM is implemented as the stage 200 of FIG. 3, the emission signal EM may be changed from the high gate voltage to the low gate voltage substantially all at once, and the horizontal line defect may not occur in the image displayed on the display panel 410. Further, the emission driver 440 may be integrated or formed in the display panel 410. In other embodiments, the emission driver 440 may be implemented as one or more integrated circuits.

The controller 450 (e.g., a timing controller) may receive input image data IDAT and a control signal CTRL from an external host processor (e.g., a graphics processing unit (“GPU”), an application processor (“AP”) or a graphics card). The input image data IDAT may be RGB image data including red image data, green image data, and blue image data. The control signal CTRL may include, but is not limited to, a vertical synchronization signal, a horizontal synchronization signal, an input data enable signal, a master clock signal, or the like. The controller 450 may generate the output image data ODAT, the data control signal DCTRL, the gate control signal GCTRL, and the emission control signal EMCTRL based on the input image data IDAT and the control signal CTRL. The controller 450 may control an operation of the data driver 420 by providing the output image data ODAT and the data control signal DCTRL to the data driver 420, may control an operation of the gate driver 430 by providing the gate control signal GCTRL to the gate driver 430, and may control an operation of the emission driver 440 by providing the emission control signal EMCTRL to the emission driver 440.

In the display device 400 according to embodiments, at least one driver of the gate driver 430 and the emission driver 440 may be implemented as the driver 100 of FIG. 1 including the stage 200 of FIG. 3, and each stage of the driver may include a boosting circuit that boosts a voltage of a second Q node to a boosted low level in case that the voltage of the second Q node becomes a low level. Accordingly, an output signal of each stage of the driver may be changed from the high gate voltage to the low gate voltage substantially all at once.

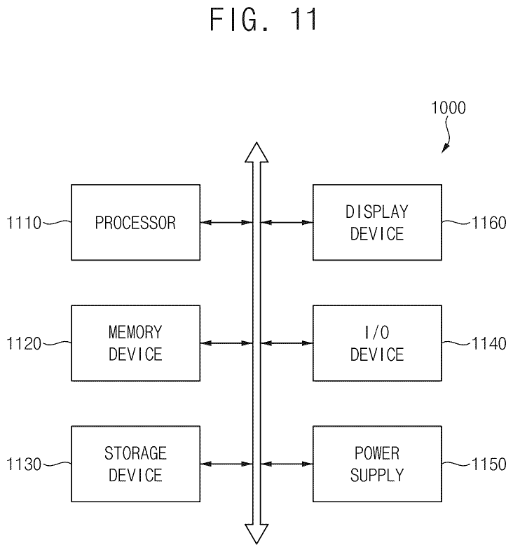

FIG. 11 is a schematic block diagram illustrating an electronic device including a display device according to embodiments.

Referring to FIG. 11, an electronic device 1000 may include a processor 1110, a memory device 1120, a storage device 1130, an input/output (“I/O”) device 1140, a power supply 1150, and a display device 1160. The electronic device 1000 may further include multiple ports for communicating with a video card, a sound card, a memory card, a universal serial bus (“USB”) device, other electric devices, etc.

The processor 1110 may perform various computing functions or tasks. The processor 1110 may be an application processor (“AP”), a micro processor, or a central processing unit (“CPU”), etc. The processor 1110 may be electrically connected to other components via an address bus, a control bus, or a data bus, etc. Further, the processor 1110 may be electrically connected to an extended bus such as a peripheral component interconnection (“PCI”) bus.

The memory device 1120 may store data for operations of the electronic device 1000. For example, the memory device 1120 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, etc., and/or at least one volatile memory device such as a dynamic random access memory (“DRAM”) device, a static random access memory (“SRAM”) device, or a mobile dynamic random access memory (mobile DRAM) device, etc.

The storage device 1130 may be a solid state drive (“SSD”) device, a hard disk drive (“HDD”) device, or a compact disc read only memory (“CD-ROM”) device, etc. The I/O device 1140 may be an input device such as a keyboard, a keypad, a mouse, or a touch screen, etc., and an output device such as a printer or a speaker, etc. The power supply 1150 may supply power for operations of the electronic device 1000. The display device 1160 may be electrically connected to other components through the buses or other communication links.

In the display device 1160, each stage of a driver may include a boosting circuit that boosts a voltage of a second Q node to a boosted low level in case that the voltage of the second Q node becomes a low level. Accordingly, an output signal of each stage of the driver may be changed from a high gate voltage to a low gate voltage at once.

The inventive concepts may be applied to any display device 1160, and any electronic device 1000 including the display device 1160. For example, the inventive concepts may be applied to a smart phone, a wearable electronic device, a mobile phone, a television (“TV”) (e.g., a digital TV or a 3D TV, etc.), a personal computer (PC) (e.g., a tablet computer, a laptop computer, etc., a home appliance, a personal digital assistant (“PDA”), a portable multimedia player (“PMP”), a digital camera, a music player, a portable game console, or a navigation device, etc.).

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A driver including a plurality of stages, at least one stage of the plurality of stages comprising:
an input circuit that transfers an input signal to a first Q node in response to a first clock signal;
a node separating circuit electrically connected between the first Q node and a second Q node;
a node controlling circuit that controls a voltage of a QB node based on a voltage of the first Q node, a high gate voltage, a low gate voltage, the first clock signal, and a second clock signal;
an output circuit that generates an output signal based on the voltage of the QB node, a voltage of the second Q node, the high gate voltage, and the low gate voltage; and
a boosting circuit that receives the voltage of the QB node, the high gate voltage, and the low gate voltage, and to boost the voltage of the second Q node to a boosted low level in case that the voltage of the second Q node becomes a low level.

2. The driver of claim 1, wherein the boosting circuit includes:
a first transistor that applies the high gate voltage to an internal node in response to the voltage of the QB node;
a second transistor that applies the low gate voltage to the internal node in response to the voltage of the second Q node; and
a first capacitor electrically connected between the second Q node and the internal node.

3. The driver of claim 2, wherein, in case that the voltage of the second Q node becomes the low level,
the first transistor is turned off in response to the voltage of the QB node such that the internal node is electrically separated from a line which transfers the high gate voltage,
the second transistor is turned on in response to the voltage of the second Q node such that a voltage of the internal node is changed from the high gate voltage to the low gate voltage, and
the first capacitor boosts the voltage of the second Q node from the low level to the boosted low level based on the voltage of the internal node changed from the high gate voltage to the low gate voltage.

4. The driver of claim 2, wherein
the first transistor includes a gate electrically connected to the QB node, a first terminal which receives the high gate voltage, and a second terminal electrically connected to the internal node,
the second transistor includes a gate electrically connected to the second Q node, a first terminal electrically connected to the internal node, and a second terminal which receives the low gate voltage, and
the first capacitor includes a first electrode electrically connected to the internal node, and a second electrode electrically connected to the second Q node. The driver of claim 1, wherein the input circuit includes:
a third transistor that transfers the input signal to the first Q node in response to the first clock signal.

6. The driver of claim 5, wherein the third transistor includes a gate which receives the first clock signal, a first terminal which receives the input signal, and a second terminal electrically connected to the first Q node.

7. The driver of claim 1, wherein the node separating circuit includes:
a fourth transistor that is turned on in response to the low gate voltage. 8 The driver of claim 7, wherein the fourth transistor includes a gate which receives the low gate voltage, a first terminal electrically connected to the first Q node, and a second terminal electrically connected to the second Q node.

9. The driver of claim 1, wherein the node controlling circuit includes:
a fifth transistor that transfers the first clock signal to a first control node in response to the voltage of the first Q node;
a sixth transistor that transfers the low gate voltage to the first control node in response to the first clock signal;
a seventh transistor electrically connected between the first control node and a second control node;
an eighth transistor that transfers the second clock signal to a third control node in response to a voltage of the second control node;
a second capacitor electrically connected between the second control node and the third control node;
a ninth transistor that electrically connects the third control node to the QB node in response to the second clock signal;
a third capacitor electrically connected between a line which transfers the high gate voltage and the QB node; and
a tenth transistor that transfers the high gate voltage to the QB node in response to the voltage of the first Q node.

10. The driver of claim 9, wherein
the fifth transistor includes a gate electrically connected to the first Q node, a first terminal electrically connected to the first control node, and a second terminal which receives the first clock signal,
the sixth transistor includes a gate which receives the first clock signal, a first terminal electrically connected to the first control node, and a second terminal which receives the low gate voltage,
the seventh transistor includes a gate which receives the low gate voltage, a first terminal electrically connected to the first control node, and a second terminal electrically connected to the second control node,
the eighth transistor includes a gate electrically connected to the second control node, a first terminal electrically connected to the third control node, and a second terminal which receives the second clock signal,
the second capacitor includes a first electrode electrically connected to the second control node, and a second electrode electrically connected to the third control node,
the ninth transistor includes a gate which receives the second clock signal, a first terminal electrically connected to the QB node, and a second terminal which receives the third control node,
the third capacitor includes a first electrode electrically connected to the line which transfers the high gate voltage, and a second electrode electrically connected to the QB node, and
the tenth transistor includes a gate electrically connected to the first Q node, a first terminal which receives the high gate voltage, and a second terminal electrically connected to the QB node.

11. The driver of claim 9, wherein the fifth transistor includes a plurality of sub-transistors electrically connected in series between the first control node and a line which transfers the first clock signal.

12. The driver of claim 1, wherein the output circuit includes:
an eleventh transistor that outputs the high gate voltage as the output signal in response to the voltage of the QB node; and
a twelfth transistor that outputs the low gate voltage as the output signal in response to the voltage of the second Q node.

13. The driver of claim 12, wherein
the eleventh transistor includes a gate electrically connected to the QB node, a first terminal which receives the high gate voltage, and a second terminal electrically connected to an output node at which the output signal is output, and
the twelfth transistor includes a gate electrically connected to the second Q node, a first terminal electrically connected to the output node, and a second terminal which receives the low gate voltage.

14. The driver of claim 1, wherein transistors included in the at least one stage are P-type metal-oxide-semiconductor (PMOS) transistors.

15. A driver including a plurality of stages, at least one stage of the plurality of stages comprising:
an input circuit that transfers an input signal to a first Q node in response to a first clock signal;
a node separating circuit electrically connected between the first Q node and a second Q node;
a node controlling circuit that controls a voltage of a QB node based on a voltage of the first Q node, a high gate voltage, a low gate voltage, the first clock signal, and a second clock signal;
an output circuit that generates an output signal based on the voltage of the QB node, a voltage of the second Q node, the high gate voltage, and the low gate voltage;
a first transistor including a gate electrically connected to the QB node, a first terminal which receives the high gate voltage, and a second terminal electrically connected to an internal node;
a second transistor including a gate electrically connected to the second Q node, a first terminal electrically connected to the internal node, and a second terminal which receives the low gate voltage; and
a first capacitor including a first electrode electrically connected to the internal node, and a second electrode electrically connected to the second Q node.

16. The driver of claim 15, wherein
the input circuit includes:
a third transistor including a gate which receives the first clock signal, a first terminal which receives the input signal, and a second terminal electrically connected to the first Q node,
the node separating circuit includes:
a fourth transistor including a gate which receives the low gate voltage, a first terminal electrically connected to the first Q node, and a second terminal electrically connected to the second Q node, the node controlling circuit includes:
a fifth transistor including a gate electrically connected to the first Q node, a first terminal electrically connected to a first control node, and a second terminal which receives the first clock signal;
a sixth transistor including a gate which receives the first clock signal, a first terminal electrically connected to the first control node, and a second terminal which receives the low gate voltage;
a seventh transistor including a gate which receives the low gate voltage, a first terminal electrically connected to the first control node, and a second terminal electrically connected to a second control node;
an eighth transistor including a gate electrically connected to the second control node, a first terminal electrically connected to a third control node, and a second terminal which receives the second clock signal;
a second capacitor including a first electrode electrically connected to the second control node, and a second electrode electrically connected to the third control node;
a ninth transistor including a gate which receives the second clock signal, a first terminal electrically connected to the QB node, and a second terminal which receives the third control node;
a third capacitor including a first electrode electrically connected to a line which transfers the high gate voltage, and a second electrode electrically connected to the QB node; and
a tenth transistor including a gate electrically connected to the first Q node, a first terminal which receives the high gate voltage, and a second terminal electrically connected to the QB node, and the output circuit includes:
an eleventh transistor including a gate electrically connected to the QB node,
a first terminal which receives the high gate voltage, and a second terminal electrically connected to an output node at which the output signal is output; and
a twelfth transistor including a gate electrically connected to the second Q node, a first terminal electrically connected to the output node, and a second terminal which receives the low gate voltage.

17. A display device comprising:
a display panel including a plurality of pixels;
a data driver that provides data signals to the plurality of pixels;
a gate driver that provides gate signals to the plurality of pixels;
an emission driver that provides emission signals to the plurality of pixels; and
a controller that controls the data driver, the gate driver, and the emission driver at least by providing inputs to each of the data driver, the gate driver, and the emission driver, wherein
at least one of the gate driver and the emission driver includes a plurality of stages, and
at least one stage of the plurality of stages includes:
an input circuit that transfers an input signal to a first Q node in response to a first clock signal;
a node separating circuit electrically connected between the first Q node and a second Q node;
a node controlling circuit that controls a voltage of a QB node based on a voltage of the first Q node, a high gate voltage, a low gate voltage, the first clock signal, and a second clock signal;
an output circuit that generates an output signal based on the voltage of the QB node, a voltage of the second Q node, the high gate voltage, and the low gate voltage; and
a boosting circuit that receives the voltage of the QB node, the high gate voltage, and the low gate voltage, and to boost the voltage of the second Q node to a boosted low level in case that the voltage of the second Q node becomes a low level.

18. The display device of claim 17, wherein the boosting circuit includes:
a first transistor that applies the high gate voltage to an internal node in response to the voltage of the QB node;
a second transistor that applies the low gate voltage to the internal node in response to the voltage of the second Q node; and
a first capacitor electrically connected between the second Q node and the internal node.

19. The display device of claim 18, wherein, in case that the voltage of the second Q node becomes the low level,
the first transistor is turned off in response to the voltage of the QB node such that the internal node is electrically separated from a line which transfers the high gate voltage,
the second transistor is turned on in response to the voltage of the second Q node such that a voltage of the internal node is changed from the high gate voltage to the low gate voltage, and
the first capacitor boosts the voltage of the second Q node from the low level to the boosted low level based on the voltage of the internal node changed from the high gate voltage to the low gate voltage.

20. The display device of claim 18, wherein
the first transistor includes a gate electrically connected to the QB node, a first terminal which receives the high gate voltage, and a second terminal electrically connected to the internal node,
the second transistor includes a gate electrically connected to the second Q node, a first terminal electrically connected to the internal node, and a second terminal which receives the low gate voltage, and
the first capacitor includes a first electrode electrically connected to the internal node and a second electrode electrically connected to the second Q node.
